(19) United States
(12) Patent Application Publication
(10) Pub. No.: US 2020/0043995 A1
(43) Pub. Date: Feb. 6, 2020

(54) TOP-EMISSION TYPE OLED DISPLAY PANEL AND MANUFACTURING METHOD THEREOF

(71) Applicant: BOE TECHNOLOGY GROUP CO., LTD., BEIJING (CN)

(72) Inventors: Dini XIE, Beijing (CN); Wei LI, Beijing (CN)

(21) Appl. No.: 16/395,740

(22) Filed: Apr. 26, 2019

(30) Foreign Application Priority Data
Aug. 2, 2018 (CN) 201810873612.X

(51) Int. Cl. H01L 27/32; H01L 51/50; H01L 51/52

(52) U.S. Cl. CPC H01L 27/3244; H01L 51/5012; H01L 2251/5315; H01L 2227/323; H01L 51/5246

(57) ABSTRACT

Embodiments of the present disclosure provide a top-emission type OLED display panel and a manufacturing method thereof. The top-emission type OLED display panel comprises an array substrate and an encapsulating cover plate, wherein the array substrate includes OLED light emitting devices which comprise a light emitting function layer, a first electrode layer disposed on a side of the light emitting function layer proximate to the encapsulating cover plate, and a second electrode disposed on a side of the light emitting function layer distal to the first electrode layer. The top-emission type OLED display panel further comprises a transparent conductive adhesive filled between the array substrate and the encapsulating cover plate, for adhering the array substrate and the encapsulating cover plate; and the transparent conductive adhesive is in direct contact with the first electrode layer.

### CROSS-REFERENCE TO RELATED APPLICATIONS

The present application claims priority to Chinese Patent Application No. 201810873612.X filed on Aug. 2, 2018, the entirety of which is hereby incorporated by reference as a part of this application.

### TECHNICAL FIELD

The present disclosure relates to a top-emission type OLED display panel and a manufacturing method thereof.

### BACKGROUND

Organic Light Emitting Display (OLED) is one of the dominant research subjects in the current display field. As compared with a liquid crystal display, the OLED display has advantages such as low power consumption, self-emission, low production cost, wide viewing angle and fast response speed. At present, for products such as mobile phones, personal digital assistants (PDA), tablets and digital cameras, the OLED display has gradually replaced the conventional liquid crystal display.

### SUMMARY

Embodiments of the present disclosure provide a top-emission type OLED display panel comprising an array substrate and an encapsulating cover plate, wherein the array substrate includes OLED light emitting devices which comprise a light emitting function layer, a first electrode layer disposed on a side of the light emitting function layer proximate to the encapsulating cover plate, and a second electrode disposed on a side of the light emitting function layer distal to the first electrode layer. The top-emission type OLED display panel further comprises a transparent conductive adhesive filled between the array substrate and the encapsulating cover plate, for adhering the array substrate and the encapsulating cover plate; and the transparent conductive adhesive is in direct contact with the first electrode layer.

In one or more embodiments of the present disclosure, the encapsulating cover plate includes a plurality of subpixel areas, and non-subpixel areas between the adjacent subpixel areas, and the non-subpixel areas of the encapsulating cover plate are provided with spacers and conductive layers; wherein the conductive layer is in direct contact with the transparent conductive adhesive.

In one or more embodiments of the present disclosure, the conductive layer is disposed on a side of the spacer proximate to the array substrate; or the conductive layer is disposed on a side of the spacer distal to the array substrate.

In one or more embodiments of the present disclosure, the material of the conductive layer includes metal.

In one or more embodiments of the present disclosure, the transparent conductive adhesive includes resin, and conductive particles doped in the resin; or, the transparent conductive adhesive is a conductive polymer having adhesivity.

In one or more embodiments of the present disclosure, the conductive particles include at least one of graphene, carbon nanotubes, C60, metal nanoparticles, or metal nanowires.

In one or more embodiments of the present disclosure, the conductive polymer includes polythiophene.

On the other hand, the present disclosure provides a manufacturing method of a top-emission type OLED display panel, comprising an array substrate and an encapsulating cover plate, wherein the array substrate includes OLED light emitting devices which comprise a light emitting function layer, a first electrode layer disposed on a side of the light emitting function layer proximate to the encapsulating cover plate, and a second electrode disposed on a side of the light emitting function layer distal to the first electrode layer, wherein the manufacturing method comprises: providing the array substrate and the encapsulating cover plate; arranging a transparent conductive adhesive between the array substrate and the encapsulating cover plate, wherein the transparent conductive adhesive is in direct contact with the first electrode layer; adhering the array substrate and the encapsulating cover plate with each other using the transparent conductive adhesive.

In one or more embodiments of the present disclosure, the transparent conductive adhesive is formed on the encapsulating cover plate.

In one or more embodiments of the present disclosure, the encapsulating cover plate includes a plurality of subpixel areas, and non-subpixel areas between the adjacent subpixel areas, and the method further comprises: forming spacers and conductive layers in the non-subpixel area of the encapsulating cover plate; wherein the conductive layer is in direct contact with the transparent conductive adhesive.

Further, in one or more embodiments of the present disclosure, the step of forming spacers and conductive layers in the non-subpixel area of the encapsulating cover plate includes: sequentially forming the spacer and the conductive layer in the non-subpixel area of the encapsulating cover plate; or, sequentially forming the conductive layer and the spacer in the non-subpixel area of the encapsulating cover plate.

### BRIEF DESCRIPTION OF THE DRAWINGS

In order to more clearly explain the embodiments of the present disclosure or the technical solutions in the relevant art, a brief introduction will be given below for the drawings required to be used in the description of the embodiments or the relevant art. It is obvious that, the drawings illustrated as follows are merely some of the embodiments of the present disclosure. For those skilled in the art, they may also acquire other drawings according to such drawings on the premise that no inventive effort is involved.

FIG. 1 is a schematic structural view of a top-emission type OLED display panel according to an embodiment of the present disclosure;

FIG. 2 is a schematic structural view of a top-emission type OLED display panel according to an embodiment of the present disclosure;

FIG. 3 is a flow chart of a manufacturing method of a top-emission type OLED display panel according to an embodiment of the present disclosure;

FIG. 4 is a schematic view of a method of forming a transparent conductive adhesive according to an embodiment of the present disclosure;

FIG. 5 is a schematic view of a method of forming a transparent conductive adhesive according to an embodiment of the present disclosure.

### DETAILED DESCRIPTION

Next, the technical solution in the embodiments of the present disclosure will be explicitly and completely described in combination with the drawings in the embodiments of the present disclosure. Apparently, the described embodiments are merely part of the embodiments of the present disclosure, rather than all the embodiments. On the basis of the embodiments of the present disclosure, all the other embodiments acquired by a person skilled in the art on the premise that no inventive effort is involved fall into the scope protected by the present disclosure.

One of the light emission modes of the OLED display is top-emission. The light exiting direction of the top-emission is a direction in which the array substrate is directed to the encapsulating cover plate. It is required that the transparency of the cathode material be as high as possible, otherwise, the display brightness of the display panel can be affected. Therefore, in order to improve the light transmittance of the cathode, the thickness of the cathode has to be made very thin. However, the thinner the thickness of the cathode is, the greater the resistance thereof will be. When there is an excessive resistance of the cathode, on one hand, the charging rate of the pixels in the OLED display can be slowed down, which affects the refreshing rate of the display screen of the OLED display, thereby affecting the viewing experience of the user On the other hand, in the case where the current is the same, there is an excessive voltage drop (IR drop) of the cathode, thereby affecting the display performance of the display panel.

Embodiments of the present disclosure provide a top-emission type OLED display panel comprising an array substrate 10 and an encapsulating cover plate 20 as shown in FIG. 2, wherein the array substrate 10 includes an OLED light emitting device 12 which comprises a light emitting function layer 122, a first electrode layer 123 disposed on one side of the light emitting function layer 122 proximate to the encapsulating cover plate 20, and a second electrode 121 disposed on one side of the light emitting function layer 122 distal to the first electrode layer 123. The top-emission type OLED display panel further comprises a transparent conductive adhesive 30 filled between the array substrate 10 and the encapsulating cover plate 20, for adhering the array substrate 10 and the encapsulating cover plate 20; wherein the transparent conductive adhesive 30 is in direct contact with the first electrode layer 123.

The transparent conductive adhesive 30 according to an embodiment of the present disclosure can not only cell-align the array substrate 10 with the encapsulating cover plate 20, but also has certain conductivity.

On such basis, the array substrate 10 further includes a substrate, and a thin film transistor 11 disposed on the substrate. The thin film transistor 11 includes a gate 111, a gate insulating layer 112, an active layer 113, a source 114, and a drain 115. The second electrode layer 121 of the OLED light emitting device 12 can be comprised of a plurality of block-shaped electrodes, and each of the block-shaped electrodes is electrically connected to the drain 115 of the thin film transistor 11 corresponding thereto. The first electrode layer 123 can be a cathode of the OLED light emitting device 12, and the second electrode layer 121 is an anode of the OLED light emitting device 12.

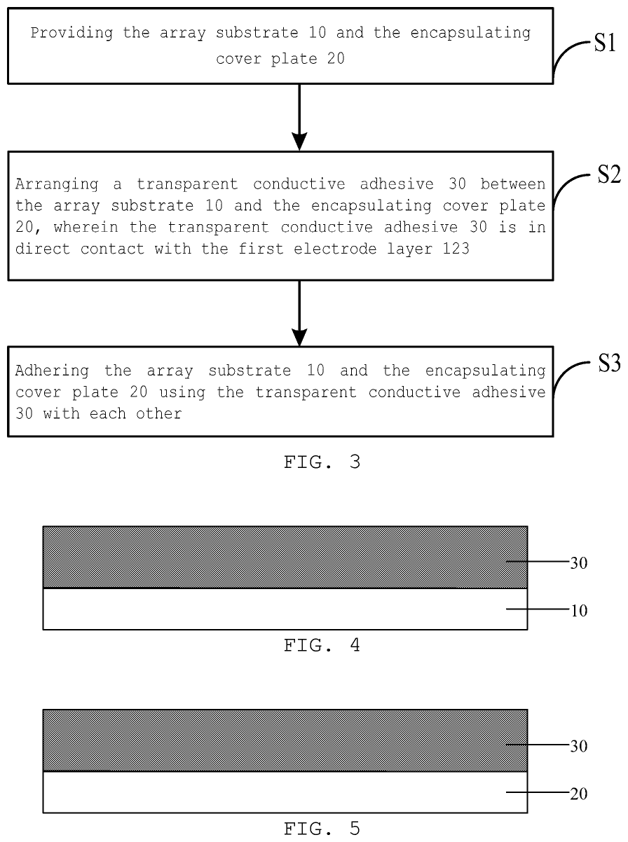

The top-emission type OLED display panel can further comprise a color filter layer and a black matrix. As shown in FIG. 3, the color filter layer 24 and the black matrix 23 are disposed on the encapsulating cover plate 20.

It should be noted that the material of the transparent conductive adhesive 30 is not limited as long as it has a certain light transmittance, adhesivity, and conductivity.

By way of example, the transparent conductive adhesive 30 includes resin and conductive particles doped in the resin. In order to make the conductive property of the transparent conductive adhesive 30 to be the same at each position, the conductive particles are uniformly doped in the resin. The conductive particles can be at least one of graphene, carbon nanotubes, C60, metal nanoparticles, and metal nanowires.

The transparent conductive adhesive 30 can also be an adhesive conductive polymer. For example, the transparent conductive adhesive 30 can be polythiophene. Before polymerization, the thiophene monomer has a certain fluidity, so that the thiophene monomer solution is coated on the encapsulating cover plate 20. After that, the thiophene monomer is subjected to ultraviolet irradiation and thermal treatment to prompt a polymerization reaction between the thiophene monomers to generate a polythiophene solid. Then, the array substrate 10 and the encapsulating cover plate 20 are attached with each other. After the polythiophene solid is cooled and cured, the cell-alignment of the array substrate 10 with the encapsulating cover plate 20 is completed.

Of course, in order to make the parallel resistance of the first electrode layer 123 and the transparent conductive adhesive 30 as small as possible, a material having a small resistivity is selected as the material of the transparent conductive adhesive 30 without changing the shape and size of the transparent conductive adhesive 30.

The material of the first electrode layer 123 is not limited, and the material of the first electrode layer 123 can be metal such as silver (Ag), aluminum (Al), calcium (Ca), indium (In), lithium (Li), magnesium (Mg). The material of the first electrode layer 123 can be a transparent conductive material such as ITO or Indium Zinc Oxide (IZO).

Embodiments of the present disclosure provide a top-emission type OLED display panel. By making the transparent conductive adhesive 30 in direct contact with the first electrode layer 123 in the OLED light emitting device 12, on the one hand, since the parallel resistance of the transparent conductive adhesive 30 and the first electrode layer 123 is smaller than the resistance of the first electrode layer 123, in the case where the first electrode layer 123 is thin, it is possible to avoid the problems that the refreshing rate of the display screen is slowed down and there is an excessive IR drop of the first electrode layer 123 resulting from an excessive resistance of the first electrode layer 123 and to improve the user's experience. On the other hand, since the transparent conductive adhesive 30 of the present application is used to adhere the array substrate 10 and the encapsulating cover plate 20, the transparent conductive adhesive 30 should be in direct contact with the first electrode layer 123, and thus it is unnecessary to electrically connect the transparent conductive adhesive 30 to the first electrode layer 123 using a manner of laser drilling or a bridging process, thereby avoiding the problem of a reduced yield of the top-emission type OLED display panel resulting from excessive difficulties in the laser drilling process or the bridging process. On the other hand, embodiments of the present disclosure do not need to add an additional structure in the top-emission type OLED panel so that it is electrically connected with the first electrode layer 123. Therefore, it is possible to simplify the steps of a process of manufacturing the top-emission type OLED display panel, and it is also possible to avoid fracture of ITO4 connecting the cathode 1 and the auxiliary electrode 2, and affect the display effect.

In one or more embodiments of the present disclosure, as shown in FIG. 3, the encapsulating cover plate 20 includes a plurality of subpixel areas, and non-subpixel areas between adjacent said subpixel areas. The non-subpixel areas of the encapsulating cover plate 20 are provided with a spacer 21 and a conductive layer 22. The conductive layer 22 is in direct contact with the transparent conductive adhesive 30.

It should be noted that, as shown in FIG. 3, the encapsulating cover plate 20 further includes a black matrix 23 and a color filter layer 24. In a display area of the top-emission type OLED display panel, the area in which the black matrix 23 is located is a non-subpixel area of the encapsulating cover plate 20, and the area other than the non-subpixel area is a subpixel area.

The projections of the spacer 21 and the conductive layer 22 on the black matrix 23 can be the same or different, as long as the projections of the spacer 21 and the conductive layer 22 on the black matrix 23 are both located within the range of the black matrix 23, and the conductive layer 22 is in direct contact with the transparent conductive adhesive 30.

The conductive layer 22 can be disposed on one side of the spacer 21 proximate to the array substrate 10 or the conductive layer 22 can also be disposed on one side of the spacer 21 distal to the array substrate 10.

When the conductive layer 22 is disposed on one side of the spacer 21 distal to the array substrate, the spacer 21 does not completely cover the conductive layer 22, so that the conductive layer 22 is in direct contact with the transparent conductive adhesive 30.

The shape of the conductive layer 22 is not limited, and the conductive layer 22 can be comprised of a plurality of block-shaped conductive blocks or a plurality of conductive strips.

The material of the conductive layer 22 is not limited, and the material of the conductive layer 22 can be a transparent conductive material such as IZO or ITO, or can be metal.

Since the conductive layer 22 is disposed in the non-subpixel area of the encapsulating cover plate 20, even if the material of the conductive layer 22 is metal, the normal display of the top-emission type OLED display panel cannot be affected.

Here, since metal has a toughness greater than that of the transparent conductive material, and metal typically has a resistivity smaller than that of the transparent conductive material, in one or more embodiments of the present disclosure, the material of the conductive layer 22 is metal.

In embodiments of the present disclosure, by providing the conductive layer 22 in the non-subpixel area of the encapsulating cover plate 20, and making the conductive layer 22 in direct contact with the transparent conductive adhesive 30, in this way, with respect to the parallel resistance of the first electrode layer 123 and the transparent conductive adhesive 30, the parallel resistance of the first electrode layer 123, the transparent conductive adhesive 30, and the conductive layer 22 can be further reduced, thereby further reducing the IR drop of the first electrode layer 123, and improving the refreshing rate of the display screen, so as to improve the user's experience.

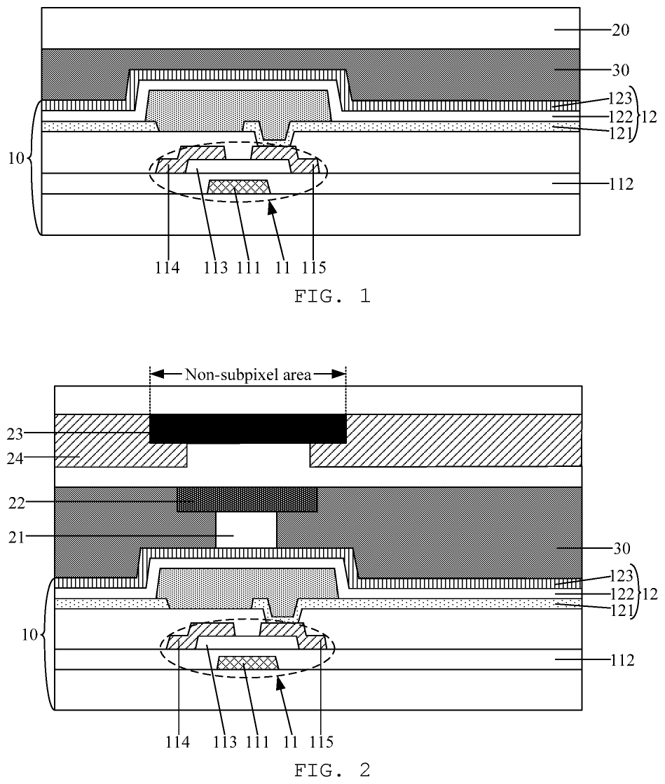

Embodiments of the present disclosure provide a manufacturing method of a top-emission type OLED display panel. As shown in FIG. 1, the top-emission type OLED display panel comprises a light emitting function layer 122, a first electrode layer 123 disposed on one side of the light emitting function layer 122 proximate to the encapsulating cover plate 20, and a second electrode 121 disposed on one side of the light emitting function layer 122 distal to the first electrode layer 123. Moreover, as shown in the flow chart of FIG. 3, the manufacturing method comprises the following steps: S1 providing the array substrate 10 and the encapsulating cover plate 20; S2 arranging a transparent conductive adhesive 30 between the array substrate 10 and the encapsulating cover plate 20, wherein the transparent conductive adhesive 30 is in direct contact with the first electrode layer 123; S3 adhering the array substrate 10 and the encapsulating cover plate 20 with each other using the transparent conductive adhesive 30.

It should be noted that the material of the transparent conductive adhesive 30 is not limited as long as it has a certain light transmittance, adhesivity, and conductivity.

By way of example, the transparent conductive adhesive 30 includes resin and conductive particles doped in the resin. In order to make the conductive property of the transparent conductive adhesive 30 to be the same at each position, the conductive particles are uniformly doped in the resin. The conductive particles can be at least one of graphene, carbon nanotubes, C60, metal nanoparticles, and metal nanowires.

The transparent conductive adhesive 30 can also be an adhesive conductive polymer. For example, the transparent conductive adhesive 30 can be polythiophene. Before polymerization, the thiophene monomer has a certain fluidity, so that the thiophene monomer solution is coated on the encapsulating cover plate 20. After that, the thiophene monomer is subjected to ultraviolet irradiation and thermal treatment to prompt a polymerization reaction between the thiophene monomers to generate a polythiophene solid. Then, the array substrate 10 and the encapsulating cover plate 20 are attached with each other. After the polythiophene solid is cooled and cured, the cell-alignment of the array substrate 10 with the encapsulating cover plate 20 is completed.

In order to make the parallel resistance of the first electrode layer 123 and the transparent conductive adhesive 30 as small as possible, a material having a small resistivity can be selected as the material of the transparent conductive adhesive 30 without changing the shape and size of the transparent conductive adhesive 30.

The material of the first electrode layer 123 is not limited, and the material of the first electrode layer 123 can be metal such as silver (Ag), aluminum (Al), calcium (Ca), indium (In), lithium (Li), magnesium (Mg). The material of the first electrode layer 123 can be a transparent conductive material such as ITO or Indium Zinc Oxide (IZO).

When the top-emission type OLED display panel is manufactured, as shown in FIG. 4, the transparent conductive adhesive 30 can be formed on the array substrate 10. As shown in FIG. 5, the transparent conductive adhesive 30 can also be formed on the encapsulating cover plate 20.

Considering that a light-emitting function layer 122 is provided on the array substrate, the light-emitting function layer 122 is susceptible to an external environment such as high temperature so that its light-emitting property is affected. Therefore, in one or more embodiments of the present disclosure, the transparent conductive adhesive 30 is formed on the encapsulating cover plate 20.

Embodiments of the present disclosure provide a manufacturing method of a top-emission type OLED display panel. By making the transparent conductive adhesive 30 in direct contact with the first electrode layer 123 in the OLED light emitting device 12, on the one hand, since the parallel resistance of the transparent conductive adhesive 30 and the first electrode layer 123 is smaller than the resistance of the first electrode layer 123, in the case where the first electrode layer 123 is thin, it is possible to avoid the problems that the refreshing rate of the display screen is slowed down and there is an excessive IR drop of the first electrode layer 123 resulting from an excessive resistance of the first electrode layer 123 and to improve the user's experience. On the other hand, since the transparent conductive adhesive 30 of the present application is used to adhere the array substrate 10 and the encapsulating cover plate 20, the transparent conductive adhesive 30 should be in direct contact with the first electrode layer 123. Accordingly, it is unnecessary to electrically connect the transparent conductive adhesive 30 to the first electrode layer 123 using a manner of laser drilling or a bridging process, thereby avoiding the problem of a reduced yield of the top-emission type OLED display panel resulting from excessive difficulties in the laser drilling process or the bridging process. On the other hand, embodiments of the present disclosure do not need to add an additional structure in the top-emission type OLED panel so that it is electrically connected with the first electrode layer 123. Therefore, it is possible to simplify the steps of a process of manufacturing the top-emission type OLED display panel, and it is also possible to avoid fracture of ITO4 connecting the cathode 1 and the auxiliary electrode 2, and affect the display effect.

In one or more embodiments of the present disclosure, as shown in FIG. 3, the encapsulating cover plate 20 includes a plurality of subpixel areas, and non-subpixel areas between adjacent said subpixel areas. The method further comprises: forming a spacer 21 and a conductive layer 22 in the non-subpixel areas of the encapsulating cover plate 20, wherein the conductive layer 22 is in direct contact with the transparent conductive adhesive 30.

It should be noted that, as shown in FIG. 3, the encapsulating cover plate 20 further includes a black matrix 23 and a color filter layer 24. In a display area of the top-emission type OLED display panel, the area in which the black matrix 23 is located is a non-subpixel area of the encapsulating cover plate 20, and the area other than the non-subpixel area is a subpixel area.

The projections of the spacer 21 and the conductive layer 22 on the black matrix 23 can be the same or different, as long as the projections of the spacer 21 and the conductive layer 22 on the black matrix 23 are both located within the range of the black matrix 23, and the conductive layer 22 is in direct contact with the transparent conductive adhesive 30.

The step of forming a spacer 21 and a conductive layer 22 in the non-subpixel areas of the encapsulating cover plate 20 includes: sequentially forming a spacer 21 and a conductive layer 22 in the non-subpixel areas of the encapsulating cover plate 20; or, sequentially forming a conductive layer 22 and a spacer 21 in the non-subpixel areas of the encapsulating cover plate 20. Here, the spacer 21 and the conductive layer 22 are both formed on one side of the encapsulating cover plate 20 proximate to the array substrate 10.

When the conductive layer 22 and the spacer 21 are sequentially formed in a non-subpixel area of the encapsulating cover plate 20, the spacer 21 does not completely cover the conductive layer 22, so that the conductive layer 22 is in direct contact with the transparent conductive adhesive 30.

The shape of the conductive layer 22 is not limited, and the conductive layer 22 can be comprised of a plurality of block-shaped conductive blocks or a plurality of conductive strips.

The material of the conductive layer 22 is not limited, and the material of the conductive layer 22 can be a transparent conductive material such as IZO or ITO, or can be metal.

Since the conductive layer 22 is disposed in the non-subpixel area of the encapsulating cover plate 20, even if the material of the conductive layer 22 is metal, the normal display of the top-emission type OLED display panel cannot be affected.

Here, since metal has a toughness greater than that of the transparent conductive material, and metal typically has a resistivity smaller than that of the transparent conductive material, in one or more embodiments of the present disclosure, the material of the conductive layer 22 is metal.

In embodiments of the present disclosure, by providing the conductive layer 22 in the non-subpixel area of the encapsulating cover plate 20, and making the conductive layer 22 in direct contact with the transparent conductive adhesive 30, in this way, with respect to the parallel resistance of the first electrode layer 123 and the transparent conductive adhesive 30, the parallel resistance of the first electrode layer 123, the transparent conductive adhesive 30, and the conductive layer 22 can be further reduced, thereby further reducing the IR drop of the first electrode layer 123, and improving the refreshing rate of the display screen, so as to improve the user's experience.

The foregoing descriptions are merely the embodiments of the present disclosure, but the protection scope of the present disclosure is not limited thereto. Anyone skilled in the art may easily anticipate a variation or a replacement within the technical scope disclosed by the present disclosure, which should all within the protection scope of the present disclosure. Thus, the protection scope of the present disclosure should be determined by the protection scope of the claims.

What is claimed is:

1. A top-emission type OLED display panel, comprising an array substrate and an encapsulating cover plate, wherein the array substrate includes OLED light emitting devices which comprise a light emitting function layer, a first electrode layer disposed on a side of the light emitting function layer proximate to the encapsulating cover plate, and a second electrode disposed on a side of the light emitting function layer distal to the first electrode layer,
the top-emission type OLED display panel further comprises a transparent conductive adhesive filled between the array substrate and the encapsulating cover plate, for adhering the array substrate and the encapsulating cover plate; and
the transparent conductive adhesive is in direct contact with the first electrode layer.

2. The top-emission type OLED display panel according to claim 1, wherein the encapsulating cover plate includes a plurality of subpixel areas, and non-subpixel areas between adjacent subpixel areas, and the non-subpixel areas of the encapsulating cover plate are provided with spacers and conductive layers;
wherein the conductive layers are in direct contact with the transparent conductive adhesive.

3. The top-emission type OLED display panel according to claim 2, wherein the conductive layers are disposed on a side of the spacers proximate to the array substrate; or the conductive layers are disposed on a side of the spacers distal to the array substrate.

4. The top-emission type OLED display panel according to claim 2, wherein a material of the conductive layers includes metal.

5. The top-emission type OLED display panel according to claim 1, wherein the transparent conductive adhesive includes resin, and conductive particles doped in the resin;
or, the transparent conductive adhesive is a conductive polymer having adhesivity.

6. The top-emission type OLED display panel according to claim 5, wherein the conductive particles include at least one of graphene, carbon nanotubes, C60, metal nanoparticles, or metal nanowires.

7. The top-emission type OLED display panel according to claim 5, wherein the conductive polymer includes polythiophene.

8. A manufacturing method of a top-emission type OLED display panel, comprising an array substrate and an encapsulating cover plate, wherein the array substrate includes OLED light emitting devices which comprise a light emitting function layer, a first electrode layer disposed on a side of the light emitting function layer proximate to the encapsulating cover plate, and a second electrode disposed on a side of the light emitting function layer distal to the first electrode layer, wherein the manufacturing method comprises:
providing the array substrate and the encapsulating cover plate;
arranging a transparent conductive adhesive between the array substrate and the encapsulating cover plate, wherein the transparent conductive adhesive is in direct contact with the first electrode layer;
adhering the array substrate and the encapsulating cover plate with each other using the transparent conductive adhesive.

9. The manufacturing method of a top-emission type OLED display panel according to claim 8, wherein arranging a transparent conductive adhesive between the array substrate and the encapsulating cover plate includes arranging the transparent conductive adhesive on the encapsulating cover plate or arranging the transparent conductive adhesive on the array substrate.

10. The manufacturing method of a top-emission type OLED display panel according to claim 8, wherein the encapsulating cover plate includes a plurality of subpixel areas, and non-subpixel areas between adjacent subpixel areas, the method further comprising:
forming spacers and conductive layers in the non-subpixel areas of the encapsulating cover plate;
wherein the conductive layers are in direct contact with the transparent conductive adhesive.

11. The manufacturing method of a top-emission type OLED display panel according to claim 10, wherein the step of forming spacers and conductive layers in the non-subpixel area of the encapsulating cover plate includes:
sequentially forming the spacers and the conductive layers in the non-subpixel areas of the encapsulating cover plate;
or, sequentially forming the conductive layers and the spacers in the non-subpixel areas of the encapsulating cover plate.
